(19) United States
(12) Patent Application Publication
(10) Pub. No.: US 2010/0006874 A1
(43) Pub. Date: Jan. 14, 2010

(54) PROCESS FOR PRODUCTION OF GALLIUM NITRIDE-BASED COMPOUND SEMICONDUCTOR LIGHT EMITTING DEVICE

(75) Inventor: Tetsuo Sakurai, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/443,332

(22) PCT Filed: Mar. 4, 2008
(86) PCT No.: PCT/JP2008/054254

§ 371 Date: Mar. 27, 2009

(30) Foreign Application Priority Data
Mar. 5, 2007 (JP) 2007-054523

(51) Int. Cl. H01L 33/00

(52) U.S. Cl. 257/94; 438/47; 257/E33.023

(57) ABSTRACT

In the process for production of a gallium nitride-based compound semiconductor light emitting device, when an n-type semiconductor layer, a light emitting layer obtained by alternately stacking an n-type dopant-containing barrier layer and a well layer, and a p-type semiconductor layer, composed of gallium nitride-based compound semiconductors, are grown in that order on a substrate, the ratio of the supply rates of n-type dopant and Group III element during growth of the barrier layer (M/III) is controlled to a range of 4.5×10⁻⁷≦(M/III)<2.0×10⁻⁶ in terms of the number of atoms.

### TECHNICAL FIELD

The present invention relates to a process for production of a gallium nitride-based compound semiconductor light emitting device with high light emission intensity and low driving voltage.

### BACKGROUND ART

Gallium nitride-based compound semiconductor light emitting devices are constructed with a configuration wherein a light emitting layer is sandwiched between an n-type semiconductor layer and p-type semiconductor layer. A voltage is applied to the light emitting device in the forward direction, and electrons and positive holes are injected from the negative electrode and positive electrode formed in contact with the n-type semiconductor layer and p-type semiconductor layer, respectively, resulting in recombination at the PN junction in the light emitting layer and emission of light. The light emitting layer is usually constructed of a well layer composed of an In-containing GaInN layer, and a GaN layer that serves as the barrier layer. That is, layers with a large band gap are situated on both sides of a layer with a small band gap, so that the injected carrier is efficiently entrapped in order to increase the probability of recombination and emission of light. The wavelength of the emitted light depends on the band gap of the GaInN layer composing the well layer, and since the band gap depends on the In composition, the light wavelength can be varied by changing the In concentration, though within a limited wavelength range. The intensity of light emission is proportional to the number of recombining positive hole and electron carriers, and therefore the composition and structure of the light emitting layer are selected so as to increase the probability of recombination. In actual practice, the thickness of the barrier layer and well layer and the concentration of the dopant material in the barrier layer are considered, as well as the production conditions for the barrier layer and well layer.

While high light emission intensity is of course desirable for a gallium nitride-based compound semiconductor light emitting device, in practice a low driving voltage (Vf) is also desired for operation of the device. Even a high light emission intensity is not practical if the driving voltage is high.

That is, it is desirable for a light emitting device to exhibit high light emission intensity at lower driving voltage when a given current (If) is supplied.

For identical electrode materials composing a light emitting device, the driving voltage depends on the composition and structure of the n-type semiconductor layer and p-type semiconductor layer and on the composition and structure of the barrier layer which forms part of the light emitting layer. In order to control the driving voltage, it is common to add dopant materials such as Si or Ge to the barrier layer. The present inventor has found; however, that increasing the dopant material concentration reduces the driving voltage but does not result in significant increase in the light emission intensity of the light emitting device. While a lower dopant material concentration will increase the light emission intensity, it also has the side-effect of requiring a higher driving voltage. In other words, although the dopant concentration in the barrier layer is a factor governing the driving voltage, it must be appropriately selected while also considering effects on the light emission intensity.

U.S. Pat. No. 6,607,595, for example, teaches control of the carrier concentration of the n-type layer by limiting the range for the ratio of the flow rates of the dopant material and other starting materials in the growth conditions. However, the relationship between this ratio and the driving voltage of the light emitting device has not been determined and is still poorly defined.

### DISCLOSURE OF INVENTION

It is an object of the present invention to solve the problems mentioned above by providing a process for production of a gallium nitride-based compound semiconductor light emitting device with high light emission intensity and low driving voltage.

The present inventor has found that by controlling the ratio of the supply rates of Group III starting material and dopant material as the constituent materials to a limited range during production of a barrier layer composed of a gallium nitride-based compound semiconductor layer, a light emitting device that is obtained using the barrier layer exhibits low driving voltage and high light emission intensity. If the ratio of the supply rates of the Group III starting material and dopant material per unit time is represented as [M/III] (M: dopant material supply rate), the limited range is 4.5×10⁻⁷≦[M/III]<2.0×10⁻⁶ in terms of number of atoms. In a gallium nitride-based compound semiconductor light emitting device comprising a light emitting layer produced with this condition, it was possible to achieve a driving voltage of 3.3 V and a light emission intensity of 14 mW, under conditions with a current of 20 mA. When [M/III]<4.5×10⁻⁷, the light emission intensity of the light emitting device is high but the driving voltage is 3.5 V or higher. Also, it was found that as [M/III] decreases, the driving voltage increases and the light emission intensity is reduced. When 2.0×10⁻⁶≦[M/III], the driving voltage varies near 3.30 V, but increasing [M/III] tends to result in lower light emission intensity.

Specifically, the invention provides the following.

(1) A process for production of a gallium nitride-based compound semiconductor light emitting device, which comprises growing an n-type semiconductor layer, a light emitting layer obtained by alternately stacking an n-type dopant-containing barrier layer and a well layer, and a p-type semiconductor layer, composed of gallium nitride-based compound semiconductors, in that order on a substrate, and then forming a negative electrode and a positive electrode on the n-type semiconductor layer and p-type semiconductor layer, respectively, the process for production of a gallium nitride-based compound semiconductor light emitting device being characterized in that the ratio of the supply rates of n-type dopant and Group III element during growth of the barrier layer (M/III) is in the range of 4.5×10⁻⁷≦(M/III)<2.0×10⁻⁶ in terms of number of atoms.

(2) A process for production of a gallium nitride-based compound semiconductor light emitting device according to (1) above, wherein the barrier layer is an n-type GaN layer.

(3) A process for production of a gallium nitride-based compound semiconductor light emitting device according to (1) or (2) above, wherein the well layer is an n-type GaInN layer.

(4) A process for production of a gallium nitride-based compound semiconductor light emitting device according to any one of (1) to (3) above, wherein the n-type dopant material is Si or Ge.

(5) A process for production of a gallium nitride-based compound semiconductor light emitting device according to any one of (1) to (4) above, wherein the internal pressure in the growth apparatus for growth of the light emitting layer is 20−60 kPa.

(6) A gallium nitride-based compound semiconductor light emitting device produced by a production process according to any one of (1) to (5) above.

(7) A lamp comprising a gallium nitride-based compound semiconductor light emitting device according to (6) above.

(8) An electronic device incorporating a lamp according to (7) above.

(9) A machine incorporating an electronic device according to (8) above.

The gallium nitride-based compound semiconductor light emitting device of the invention, which is produced by controlling the ratio of the supply rates of n-type dopant and Group III element during growth of the barrier layer to within a specified range, has high light emission intensity and low driving voltage.

### BRIEF DESCRIPTION OF THE DRAWINGS

FIG. 1 is a schematic view showing the cross-section of an example of a gallium nitride-based compound semiconductor light emitting device comprising a light emitting layer according to the invention.

FIG. 2 is graph showing driving voltage (Vf) and light emission output (Po) plotted against [Si/Ga] during barrier layer growth, obtained for the examples and comparative examples.

### BEST MODE FOR CARRYING OUT THE INVENTION

The present invention will now be explained in greater detail.

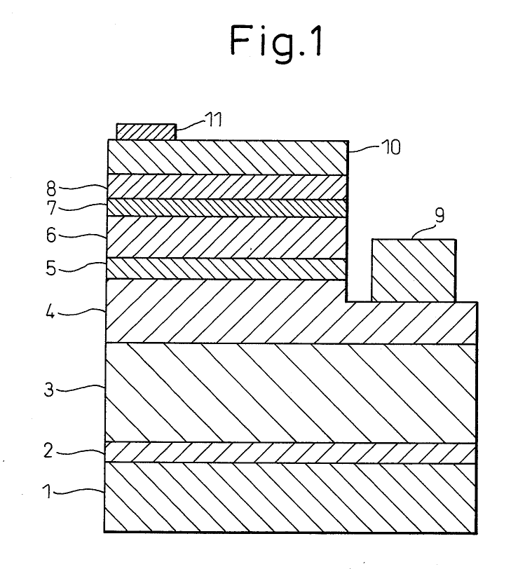

FIG. 1 is a schematic view showing the cross-section of an example of a gallium nitride-based compound semiconductor light emitting device comprising a light emitting layer according to the invention. In FIG. 1, 1 is a substrate, 2 is a buffer layer, 3 is an underlying layer composed of undoped GaN, for example, 4 is an n-type contact layer composed of GaN, for example, 5 is an n-type clad layer composed of GaₓIn₁₋ₓN, for example, and 6 is a light emitting layer. The light emitting layer is obtained by alternately stacking a barrier layer composed of GaN and a well layer composed of In-containing GaₓIn₁₋ₓN. The layers labeled 7 and 8 are the p-type clad layer and p-type contact layer. The layer labeled 9 is a negative electrode material situated in contact with the n-type contact layer. A transparent electrode material, labeled 10, is situated on the p-type contact layer, and a bonding pad layer labeled 11 is situated thereover. The transparent electrode material and bonding pad layer form the positive electrode.

The invention will now be explained in further detail with reference to FIG. 1.

According to the invention, the substrate labeled 1 in FIG. 1 may be made of a known substrate material selected from among oxide single crystal substrates such as sapphire single crystal (Al₂O₃; A-plane, C-plane, M-plane, R-plane), spinel single crystal (MgAl₂O₄), ZnO single crystal, LiAlO₂ single crystal, LiGaO₂ single crystal, MgO single crystal or Ga₂O₃ single crystal, and non-oxide single crystal substrates such as Si single crystal, SiC single crystal, GaAs single crystal, AlN single crystal, GaN single crystal and boride single crystals such as ZrB₂. There are no particular restrictions on the plane direction of the substrate, and the off-angle may be selected as desired. A surface-processed substrate may also be used.

Semiconductors with various compositions represented by the general formula AlₓGa_{1-x-y}In_{y}N (0≦x≦1, 0≦y≦1, 0≦x+y≦1) are well known as gallium nitride-based compound semiconductors for buffer layers, underlying layers, n-type contact layers, n-type clad layers, light emitting layers, p-type clad layers and p-type contact layers. Semiconductors with various compositions represented by the general formula AlₓGa_{1-x-y}In_{y}N (0≦x≦1, 0≦y≦1, 0≦x+y≦1) may also be used as gallium nitride-based compound semiconductors for the buffer layer, underlying layer, n-type contact layer, n-type clad layer, light emitting layer, p-type clad layer and p-type contact layer of the invention, although there is no limitation to these.

Any method may also be used for growing these gallium nitride-based compound semiconductors according to the invention, such as metal-organic chemical vapor deposition (MOCVD), molecular beam epitaxy (MBE), hydride vapor phase epitaxy (HVPE) and the like. MOCVD is preferred for easier composition control and increased productivity, but there is no limitation to this method.

When MOCVD is employed as the growth method for the semiconductor layer, the organometallic materials trimethylgallium (TMGa) or triethylgallium (TEGa) will usually be selected as the Group III Ga starting material. Trimethylaluminum (TMAl) or triethylaluminum (TEAl) is used as the Group III Al starting material. The starting material for In, which is one of the constituent starting materials of the well layer in the light emitting layer, may be trimethylindium (TMIn) or triethylindium (TEIn). As a Group V N source there may be used ammonia (NH₃) or hydrazine (N₂H₄).

Si or Ge is used as the dopant material in the barrier layer inside the light emitting layer and the n-type contact layer. As Si starting materials there may be used monosilane (SiH₄) or disilane (Si₂H₆), and as Ge starting materials there may be used germane (GeH₄) or organic germanium compounds.

Mg may be used as the dopant in the p-type clad layer and p-type contact layer. The Mg starting material may be biscyclopentadienylmagnesium (Cp₂Mg) or bisethylcyclopentadienylmagnesium ((EtCp)₂Mg), for example.

Each semiconductor layer will now be explained, assuming application of common MOCVD as the method of growing the gallium nitride-based compound semiconductor.

(Buffer Layer)

As buffer layers there are known the low-temperature buffer layer disclosed in Japanese Patent No. 3026087 and the high-temperature buffer layer disclosed in Japanese Unexamined Patent Publication No. 2003-243302, but there is no restriction to using these buffer layers.

The substrate used for growth may be any one selected from among those mentioned above, but a sapphire substrate will be used for the following explanation.

The substrate is placed on a SiC film-attached graphite jig (susceptor) situated in a reaction space with variable temperature and pressure. Hydrogen carrier gas or nitrogen carrier gas controlled to the prescribed supply rate are fed into the site together with NH₃ gas and TMAl. The SiC film-attached graphite jig is heated to the necessary temperature by induction heating with an RF coil, forming an AlN buffer layer on the substrate. An appropriate furnace pressure at this time is 10-40 kPa (100-400 mbar). The temperature is controlled to between 500° C. and 700° C. in order to grow an AlN low-temperature buffer layer, and then raised to about 1100° C. for crystallization. Growth of a high temperature AlN buffer layer may be accomplished by a single growth step at a temperature of between 1000° C. and 1200° C., instead of heating in two stages. Growth of the buffer layer is not necessarily required when the aforementioned AlN single crystal substrate or GaN single crystal substrate is used, and an undoped GaN layer described hereunder may be directly grown as an underlying layer on the substrate.

(Underlying Layer and N-Type Contact Layer)

The underlying layer labeled as 3 in FIG. 1 and the n-type contact layer labeled as 4 will now be described.

Following formation of the buffer layer, an underlying layer is grown on the buffer layer. Underlying layers with different compositions and structures are known. A underlying layer with any composition and structure among those known may also be used for the invention, although one composed of an undoped GaN layer is preferred.

With a temperature of 1000-1200° C. and under pressure control, NH₃ gas and TMGa are fed onto the buffer layer together with a carrier gas consisting of nitrogen gas, hydrogen gas or a mixture thereof. The amount of TMGa fed is limited by its specified proportion with respect to the simultaneously flowing NH₃, but control to a growth rate of between 1 μm/hr and 3 μm/hr is effective for inhibiting crystal defects such as dislocations. The growth pressure is optimally in the range of 20−60 kPa (200-600 mbar) in order to ensure the growth rate specified above.

An n-type contact layer is grown after growth of the underlying layer. The n-type contact layer may also have any known composition and structure. A layer with any composition and structure among those known may also be used for the invention, although one composed of a GaN layer doped with an n-type impurity is preferred.

The growth conditions for the n-type GaN layer are the same as the growth conditions for the undoped GaN layer. The dopant used is Si or Ge, which is supplied together with the carrier gas. The supply concentration is limited by the proportion with respect to the TMGa supply rate. The present invention realizes a high-emission semiconductor device with low driving voltage by controlling the proportion of the dopant material supply rate and the Ga starting material supply rate to the barrier layer in the light emitting layer described hereunder, but since the driving voltage is also affected by the n-type contact layer dopant concentration and the p-type semiconductor layer dopant concentration, these concentrations are determined in accordance with the growth conditions. As a condition for supply of the dopant to the n-type GaN contact layer, the M/III ratio (M=Si or Ge) is in the range of 1.0×10⁻⁵-6.0×10⁻⁵.

The film thickness for an underlying layer composed of undoped GaN, for example, is preferably 4-7 μm, while for an n-type contact layer composed of GaN it is preferably 2-4 μm, but there is no particular limitation to these ranges. The film thicknesses of the underlying layer and n-type contact layer may be increased as a way of preventing propagation of crystal defects from the substrate and buffer layer to the upper layers, but this is not advisable since increasing the thickness induces warping of the wafer itself. According to the invention, it is preferred for the film thickness of each layer to be established within the range specified above.

(n-Type Clad Layer)

An n-type clad layer is grown on the n-type contact layer. The n-type clad layer may also have a known composition and structure. A layer with any composition and structure among those known may also be used for the invention, although one composed of a GaₓIn₁₋ₓN layer is preferred.

The Ga starting material used to form the GaₓIn₁₋ₓN layer may be TEGa or TMGa, and the In starting material may be TMIn. The growth temperature may be selected between 700° C. and 1000° C., with the starting materials and NH₃ being supplied by a carrier gas onto the n-type contact layer which is kept at that temperature.

The carrier gas is preferably nitrogen gas for supply of TMIn. A hydrogen carrier will interfere with incorporation of In. The growth pressure is preferably 20−60 kPa (200-600 mbar) according to the invention, but there is no necessary limitation to this range.

The compositional ratio of In in the GaₓIn₁₋ₓN is not restricted but is preferably no greater than 10%. The composition may be controlled by the ratio of the supply of TMIn with respect to the Ga starting material.

The dopant gas is supplied simultaneously to obtain an n-type material, with an M/III ratio (M=Si or Ge) in the range of 1.0×10⁻⁶-2.0×10⁻⁶.

(Light Emitting Layer)

The light emitting layer is formed while alternately stacking the barrier layer and well layer. The carrier gas selected for use is N₂. The NH₃ and TEGa or TMGa are supplied together with the carrier gas. According to the invention, the dopant material is contained in the barrier layer.

Well layers with different compositions and structures are known. A layer with any composition and structure among those known may also be used for the invention, although one composed of a GaₓIn₁₋ₓN layer is preferred.

TEGa and TMIn are supplied for growth of the GaₓIn₁₋ₓN layer as the well layer. The In concentration is determined from the supply rate of TMIn, and its supply rate will depend on the desired light wavelength. Since it is difficult to control the In concentration when H₂ is present in the carrier gas, it is inadvisable to use H₂ as the carrier gas for this layer. The film thickness of the GaₓIn₁₋ₓN layer is selected for maximal light emission intensity.

The growth temperature is preferably between 700° C. and 1000° C., although there is no necessary limitation to this range. However, a high temperature during growth of the well layer will inhibit incorporation of In into the growing film, thus substantially hampering formation of the well layer. The growth temperature is therefore selected in a range that is not too high. It is preferred not to supply the dopant material during growth of the well layer.

Barrier layers with different compositions and structures are also known. A barrier layer with any composition and structure among those known may also be used for the invention, although it must contain the dopant material. A GaN layer containing the dopant material is preferably used.

For growth of a barrier layer composed of a dopant material-containing gallium nitride-based compound semiconductor layer, the ratio between the dopant material supply rate and Group III element supply rate M/III is important. These supply rates are determined from the conditions established for the massflow controller used, and the ratio is [M/III]. The [M/III] ratio is controlled to be in a range of 4.5×10⁻⁷≦M/III<2×10⁻⁶ in terms of number of atoms. Either Si or Ge may be used as the dopant. While TMGa or TEGa may be selected as the Group III element Ga starting material, TEGa is preferred in order to facilitate control of the supply concentration and to facilitate alternate stacking with the well layer. The carrier gas is preferably nitrogen gas. The growth temperature may be between 700° C. and 1000° C., but there is no problem with varying the growth temperature for the well layer and barrier layer.

The growth pressure is set in balance with the growth rate. The growth pressure is preferably 20−60 kPa (200-600 mbar) according to the invention, but is not necessarily limited to this range.

The number of barrier layers and well layers is suitably between 3 and 7 for each, although there is no necessary limitation to this range. The light emitting layer is completed upon growth of the final barrier layer. The barrier layer prevents carrier overflow from the well layer while also acting to prevent re-dissociation of In from the final well layer during growth of the p-type clad layer.

(p-Type Clad Layer and p-Type Contact Layer)

A p-type clad layer is stacked directly over the final barrier layer of the light emitting layer, and a p-type contact layer is stacked thereover. GaN or GaAlN is preferably used for the p-type clad layer and p-type contact layer. During this time, layers with different compositions or lattice constants may be alternately stacked and the thicknesses of the layers and the dopant Mg concentrations may be varied. The Al concentration is preferably higher in the p-type clad layer than in the p-type contact layer. The p-type contact layer does not necessarily need to contain Al. Hydrogen may exist in the p-type clad layer and p-type contact layer with the Mg dopant, at a concentration of about 1×10¹⁸-1×10²¹ atoms/cm³.

The supply rate of the Mg dopant during growth of the p-type clad layer and p-type contact layer is not particularly restricted, but the dopant concentration in the p-type layer is preferably controlled to 0.9×10²⁰-2×10²⁰ atoms/cm³, in order to ensure a crystalline state.

Growth of the p-type clad layer and p-type contact layer is accomplished in the following manner. TMGa, TMAl and the dopant Cp₂Mg are fed onto the light emitting layer together with a carrier gas (hydrogen or nitrogen, or a mixture thereof) and NH₃ gas.

The growth temperature during this time is preferably in the range of 980-1100° C. At a lower temperature than 980° C., a low-crystallinity epitaxial layer will form, thus increasing the film resistance due to crystal defects. At a higher temperature than 1100° C., the well layer, in the light emitting layer located thereunder, will be situated in a high temperature environment during the p-type semiconductor layer growth process, potentially undergoing thermal damage. This can lower the light emission intensity of the eventually formed light emitting device or reduce the light emission intensity in resistance testing.

The growth pressure is not particularly restricted but is preferably no greater than 50 kPa (500 mbar). This is because growth in this pressure range can produce a more uniform Al concentration in the in-plane direction, thus facilitating control when growing a p-type clad layer and p-type contact layer with variation of the Al composition of the GaAlN as necessary. Under conditions with a higher pressure, reaction between the supplied TMAl and NH₃ becomes dominant causing the TMAl to be consumed before it reaches the substrate, and making it difficult to obtain the desired Al composition. The same applies for Mg that is fed as the dopant. That is, if the growth conditions are below 50 kPa (500 mbar), the Mg concentration distribution in the p-type semiconductor layer will be homogeneous in the two-dimensional direction (the in-plane direction of the growth substrate).

It is known that the Al composition and Mg concentration distribution in the in-plane direction of the AlGaN contact layer vary depending on the flow rate of the carrier gas used. However, it has been found that the in-plane uniformity of the Al composition and Mg in the p-type contact layer are more significantly affected by the growth pressure conditions than by the carrier gas conditions. Therefore, a growth pressure of not greater than 50 kPa (500 mbar) and at least 10 kPa (100 mbar) is most suitable.

Following growth of the p-type contact layer, heating of the substrate is stopped while feeding in N₂ gas to purge the reaction space, and the wafer is cooled and removed out of the growth apparatus. It has been confirmed that the p-type contact layer at this point is the target p-type layer. Subsequent heat treatment for activation is therefore unnecessary.

(Negative Electrode and Positive Electrode)

Various compositions and structures are known for negative electrodes and positive electrodes, and any known compositions and structures may also be employed for the invention. Various processes are also known for their production, and any such known processes may be employed.

A known photolithography technique and ordinary etching technique may be used to form the negative electrode-forming side on the n-type GaN contact layer. Such techniques allow etching from the uppermost layer of the wafer up to the location of the n-type contact layer, thus exposing the n-type contact layer at the negative electrode-forming regions. As negative electrode materials there may be used metal materials such as Al, Ti, Ni and Au, as well as Cr, W and V, as contact metals for contact with the n-type contact layer. In order to improve adhesiveness with the n-type contact layer, a multilayer structure may be used that comprises a combination of several contact metals selected from among the aforementioned metals. Using Au for the uppermost surface will result in satisfactory bonding properties.

Various compositions and structures are known for the positive electrode to be formed on the p-type contact layer, including reflective positive electrodes or transparent electrode materials such as ITO films, and any compositions and structures may be employed including these known types.

Various compositions and structures are known for bonding pad layer materials as well, and any compositions and structures, including known ones, may also be employed for the invention without any particular restrictions. The thickness must be sufficient so that the stress during bonding does not damage the positive electrode. The uppermost layer is preferably a material such as Au that has satisfactory adhesiveness with the bonding ball.

The gallium nitride-based compound semiconductor light emitting device obtained by the production process of the invention may be incorporated into a lamp by providing a transparent cover using any means well known to those skilled in the art. The gallium nitride-based compound semiconductor light emitting device obtained by the production process of the invention may also be combined with a cover with a phosphor-containing to produce a white lamp.

Since a lamp made from a gallium nitride-based compound semiconductor light emitting device obtained by the production process of the invention has high light emission intensity and low driving voltage, electronic devices such as cellular phones, displays, panels and the like incorporating lamps made with this technology, or machines such as automobiles, computers or game devices incorporating such electronic devices, can be driven with low electric power while exhibiting high characteristics. The effect of reduced power consumption is particularly desirable for battery-driven devices such as cellular phones, game devices, toys and automobile parts.

### EXAMPLES

The present invention will now be explained in greater detail by examples and comparative examples, with the understanding that the invention is in no way limited only to the examples.

### Example 1

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied with SiH₄ as the dopant, without changing the growth pressure or growth temperature, for 7-minute growth of a barrier layer. The [Si/Ga] per unit time was 5.7×10⁻⁷ in terms of number of atoms. Additional TMIn was then supplied for 5-minute growth of a well layer composed of GaₓIn₁₋ₓN. The TMIn supply rate was adjusted for an In composition of 1−X=0.08. The supply of SiH₄ was terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed out of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.42 V and 14.4 mW, respectively.

### Example 2

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied with SiH₄ as the dopant, without changing the growth pressure or growth temperature, for 7-minute growth of a barrier layer. The [Si/Ga] per unit time was 8.4×10⁻⁷ Additional TMIn was then supplied for 5-minute growth of a well layer composed of GaₓIn₁₋ₓN. The TMIn supply rate was adjusted for an In composition of 1−X=0.08. The supply of SiH₄ was terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed out of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.29 V and 14.2 mW, respectively.

### Example 3

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied with SiH₄ as the dopant, without changing the growth pressure or growth temperature, for 7-minute growth of a barrier layer. The [Si/Ga] per unit time was 14×10⁻⁷. Additional TMIn was then supplied for 5-minute growth of a well layer composed of GaₓIn₁₋ₓN. The TMIn supply rate was adjusted for an In composition of 1−X=0.08. The supply of SiH₄ was terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed out of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.27 V and 13.4 mW, respectively.

### Example 4

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied with SiH₄ as the dopant, without changing the growth pressure or growth temperature, for 7-minute growth of a barrier layer. The [Si/Ga] per unit time was 19×10⁻⁷. Additional TMIn was then supplied for 5-minute growth of a well layer composed of GaₓIn₁₋ₓN. The TMIn supply rate was adjusted for an In composition of 1−X=0.08. The supply of SiH₄ was terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed from of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.30 V and 13.3 mW, respectively.

### Comparative Example 1

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied without changing the growth pressure or growth temperature, for 7-minute growth of a barrier layer. No dopant gas was supplied. Additional TMIn was then supplied for 5-minute growth of a well layer composed of GaₓIn₁₋ₓN. The TMIn supply rate was adjusted for an In composition of 1−X=0.08. The supply of SiH₄ was also terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed out of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.95 V and 11.0 mW, respectively.

### Comparative Example 2

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied with SiH₄ as the dopant, without changing the growth pressure or growth temperature, for 7-minute growth of a barrier layer. The [Si/Ga] per unit time was 2.8×10⁻⁷. Additional TMIn was then supplied for 5-minute growth of a well layer composed of GaₓIn₁₋ₓN. The TMIn supply rate was adjusted for an In composition of 1−X=0.08. The supply of SiH₄ was terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed out of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.56 V and 13.9 mW, respectively.

### Comparative Example 3

A sapphire substrate was set on a susceptor, and TMAl and NH₃ were supplied together with H₂ carrier gas onto the substrate while controlling the pressure to 20 kPa (200 mbar) and the temperature to 1100° C., to form an AlN buffer layer. The growth time was 10 minutes.

Next, TMGa and NH₃ were supplied with a pressure of 40 kPa (400 mbar) and a temperature of 1030° C. for 3-hour growth of an undoped GaN underlying layer on the AlN buffer layer. SiH₄ was then supplied as an n-type dopant while maintaining the same pressure and temperature, for 1-hour growth of an n-type GaN layer. This procedure formed an n-type contact layer.

Next, the carrier gas was switched from H₂ to N₂ with a pressure of 40 kPa (400 mbar) and a temperature of 750° C., and TEGa and TMIn were supplied for 90-minute growth of an n-type GaₓIn₁₋ₓN layer. SiH₄ was simultaneously supplied as the dopant. The TMIn supply rate was adjusted for an In composition of 1−X=0.02. This procedure formed an n-type clad layer.

Next, TEGa and NH₃ were supplied with SiH₄ as the dopant, without changing the growth pressure or growth temperature, for 7-minute growth of a barrier layer. The [Si/Ga] per unit time was 23×10⁻⁷. Additional TMIn was then supplied for 5-minute growth of a well layer composed of GaₓIn₁₋ₓN. The TMIn supply rate was adjusted for an In composition of 1−X=0.08. The supply of SiH₄ was terminated during growth of the well layer.

Growth of the barrier layer and well layer was repeated alternately 5 times, and the final barrier layer was grown to form a light emitting layer.

The carrier gas was then again switched to H₂ and TMGa and TMAl were supplied with a pressure of 20 kPa (200 mbar) and a temperature of 1000° C., while feeding Cp₂Mg as the dopant for 3-minute growth of a p-type clad layer. This was followed by 15-minute growth of a p-type contact layer while maintaining the same pressure and temperature. The TMAl supply rate was lower than for the p-type clad layer.

Introduction of electric power to the induction coil was then interrupted, heating was stopped and the carrier gas was switched to N₂ to purge the furnace while cooling to a temperature allowing the obtained gallium nitride-based compound semiconductor stacked structure to be removed out of the furnace.

A section of the n-type contact layer of the gallium nitride-based compound semiconductor stacked structure removed out of the furnace was exposed by photolithography and dry etching and a negative electrode composed of a metal layer of Cr and Ti was formed thereover. An ITO film with a thickness of 350 nm was formed on the p-type contact layer by vapor deposition, and then a bonding pad layer obtained by stacking Ti, Au, Al and Au in that order was formed thereover to obtain a positive electrode. After polishing and scribing the back of the substrate, it was segmented into separate light emitting devices.

A current of 20 mA was applied to the obtained light emitting device to produce light emission, and the driving voltage (Vf) and light emission output (Po) measured at that time were 3.23 V and 12.6 mW, respectively.

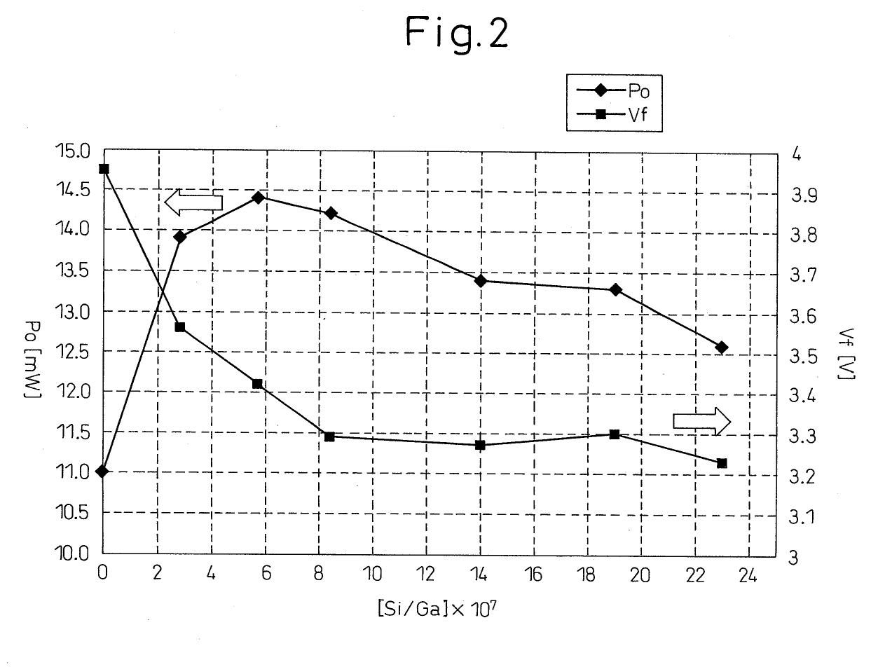

Table 1 lists the results for the examples and comparative examples described above, and FIG. 2 shows a graph of the results. As seen from the table and the drawing, the driving voltage was high in Comparative Examples 1 and 2, wherein [Si/Ga] during barrier layer formation was smaller than 4.5×10⁻⁷ in terms of number of atoms. The light emission output was low in Comparative Example 3, wherein [Si/Ga] during barrier layer formation was greater than 2.0×10⁻⁶ in terms of the number of atoms.

TABLE 1

| | [Si/Ga] ratio of | | |
|---|---|---|---|
| | barrier layer | | |
| | (×10⁷) | Po[mW] | Vf[V] |
| Comp. Example 1 | 0.0 | 11.0 | 3.95 |
| Comp. Example 2 | 2.8 | 13.9 | 3.56 |
| Example 1 | 5.7 | 14.4 | 3.42 |
| Example 2 | 8.4 | 14.2 | 3.29 |
| Example 3 | 14.0 | 13.4 | 3.27 |
| Example 4 | 19.0 | 13.3 | 3.30 |
| Comp. Example 3 | 23.0 | 12.6 | 3.23 |

### INDUSTRIAL APPLICABILITY

A gallium nitride-based compound semiconductor light emitting device obtained by the production process of the invention has satisfactory light emission output and low driving voltage, and therefore it is of very high industrial value.

1. A process for production of a gallium nitride-based compound semiconductor light emitting device, which comprises growing an n-type semiconductor layer, a light emitting layer obtained by alternately stacking an n-type dopant-containing barrier layer and a well layer, and a p-type semiconductor layer, composed of gallium nitride-based compound semiconductors, in that order on a substrate, and then forming a negative electrode and a positive electrode on the n-type semiconductor layer and p-type semiconductor layer, respectively, the process for production of a gallium nitride-based compound semiconductor light emitting device being characterized in that the ratio of the supply rates of n-type dopant and Group III element during growth of the barrier layer (M/III) is in the range of 4.5×10⁻⁷≦(M/III)<2.0×10⁻⁶ in terms of number of atoms.

2. A process for production of a gallium nitride-based compound semiconductor light emitting device according to claim 1, wherein the barrier layer is an n-type GaN layer.

3. A process for production of a gallium nitride-based compound semiconductor light emitting device according to claim 1, wherein the well layer is an n-type GaInN layer.

4. A process for production of a gallium nitride-based compound semiconductor light emitting device according to claim 1, wherein the n-type dopant material is Si or Ge.

5. A process for production of a gallium nitride-based compound semiconductor light emitting device according to claim 1, wherein the internal pressure in the growth apparatus for growth of the light emitting layer is 20−60 kPa.

6. A gallium nitride-based compound semiconductor light emitting device produced by a production process according to claim 1.

7. A lamp comprising a gallium nitride-based compound semiconductor light emitting device according to claim 6.

8. An electronic device incorporating a lamp according to claim 7.

9. A machine incorporating an electronic device according to claim 8.
